(19) United States
(12) Patent Application Publication
(10) Pub. No.: US 2010/0197068 A1
(43) Pub. Date: Aug. 5, 2010

(54) Hybrid Transparent Conductive Electrode

(76) Inventors: Hak Fei Poon, Sunnyvale, CA (US); Tianyue Yu, Sunnyvale, CA (US)

Correspondence Address: Director of IP, 5521 Hellyer Avenue, San Jose, CA, 95138, US

(21) Appl. No.: 12/610,247

(22) Filed: Oct. 30, 2009

Related U.S. Application Data
(60) Provisional application No. 61/109,898, filed on Oct. 30, 2008.

(51) Int. Cl. H01L 31/18

(52) U.S. Cl. 438/63; 438/72; 977/762; 257/E31.032; 257/E31.119; 257/E31.126

(57) ABSTRACT

Methods and devices are provided for improved photovoltaic devices. In one embodiment, the transparent electrode of a thin-film solar cell is replaced in part by a sheet of nanowires. One technique for use in present invention comprises forming a solar cell having: a) a thinner than usual transparent top electrode of a conductive material having a reduced thickness and b) an interconnected network of nanowires in contact with and/or coated by the top electrode. In some embodiments, the top electrode and network of nanowires increases overall power output of the solar cell compared to an otherwise identical cell using only a) a top electrode layer of the material at a thickness and light transmission equal to a combined thickness and light transmission of the top electrode and the network of nanowires, or b) an interconnected network of nanowires of thickness equal to the combined thickness and light transmission.

### CROSS-REFERENCE TO RELATED APPLICATION

This application claims priority to U.S. Provisional Application Ser. No. 61/109,898 filed Oct. 30, 2008 and fully incorporated herein by reference for all purposes.

### FIELD OF THE INVENTION

The present invention is directed to depositing transparent conductive electrodes (TCE) on large area substrates and more specifically to non-vacuum TCE deposition in high-throughput roll-to-roll production systems for use in photovoltaics.

### BACKGROUND OF THE INVENTION

Solar cells and solar modules convert sunlight into electricity. These electronic devices have been traditionally fabricated using silicon (Si) as a light-absorbing, semiconducting material in a relatively expensive production process. To make solar cells more economically viable, solar cell device architectures have been developed that can inexpensively make use of thin-film, light-absorbing semiconductor materials such as copper-indium-gallium-selenide (CIGS) and the resulting devices are often referred to as CIGS solar cells.

A central challenge in cost-effectively constructing a large-area CIGS-based solar cell or module involves reducing processing costs and material costs. In known versions of CIGS solar cells, the transparent conductive electrode (TCE) layer and many other layers are deposited by a vacuum-based process depositing over a glass or metal substrate. Typical deposition techniques include co-evaporation, sputtering, chemical vapor deposition, or the like. One of the most common techniques used to deposit transparent conductive electrodes (TCE) is sputter deposition of transparent conductive oxides (TCO). Unfortunately, for the film thickness and high vacuum required, sputter deposition is a slow process with an undesired low throughput/capex ratio. In addition, material yield is low due to deposition of material onto the chamber walls. Furthermore, temperature control during sputter deposition can limit the throughput even further, especially when damage of underlying temperature-sensitive layers, like e.g. the CIGSe/CdS stack, needs to be prevented. Finally, controlling the large-area uniformity of both the conductivity and transparency of a sputter-deposited TCO is challenging.

In addition to the slower processing to deposit layers TCO on top a thin film solar cells, it should also be understood that the TCO materials themselves used as the TCE are not proper conductors, with sheet resistance typically being at least 5 Ohms/□ for the most expensive products and often more than 60-200 Ohms/□ for lower-priced materials. Solar cells formed using such TCO's depend on an interconnect scheme that uses additional conductive patterns (traces, fingers, grids, lines, bus bars, etc.) to collect the current with minimal electrical-resistive and optical-shadowing losses. As a result, there is currently a tradeoff when integrating the TCO material into thin-film solar cells related either to depositing very thick or very expensive layers of TCO or from losses associated with additional conductive patterns used with the TCO.

Some prior techniques have been suggested using a network of metal nanowires or carbon nanotubes as a low cost alternative to sputtered transparent conductive oxide electrodes. However, in general the efficiency of the cells is lacking compared to sputtered TCO.

Due to the aforementioned issues, improved techniques may be used for reducing processing costs and material costs. Improvements may be made to increase the throughput of existing manufacturing processes and decrease the cost associated with CIGS based solar devices. The decreased cost and increased production throughput should increase market penetration and commercial adoption of such products.

### SUMMARY OF THE INVENTION

Embodiments of the present invention address at least some of the drawbacks set forth above. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. In one embodiment, the techniques discussed herein will work on printed & rapid thermally processed CIGS, CIGSS, or other absorber layer to reduce or eliminate the amount of TCO material that is sputtered or chemical vapor deposited thereon. At least some of the embodiments herein will improve the contact area between the nanowires and the absorber/active layer (e.g. CIGS/CdS), and thus increase the amount of photocurrent that is collected. At least some of these and other objectives described herein will be met by various embodiments of the present invention.

In one embodiment of the present invention, the transparent electrode of a thin-film CIGS solar cell is replaced in part by a sheet of nanowires. One embodiment of a technique for use in present invention comprises forming a solar cell having: a) a thinner than usual transparent top electrode of a conductive material having a thickness of 50 nm or less and b) an interconnected network of nanowires in contact with and/or coated by the top electrode. In some embodiments, the top electrode and network of nanowires increases overall power output of the solar cell compared to an otherwise identical cell using only a) a top electrode layer of the material at a thickness and light transmission equal to a combined thickness and light transmission of the top electrode and the network of nanowires, or b) an interconnected network of nanowires of thickness equal to the combined thickness and light transmission.

It should be understood that for any of the embodiments herein, the following may optionally also apply. Optionally, the nanowires are coated plainly in a solvent only and no binder. Optionally, the method includes subsequently overcoating the nanowires with a binder. Optionally, the binder is an electrically conductive polymer. Optionally, the binder is a viscosity modifier. Optionally, the nanowires are coated onto the solar cell and subsequently pressed into it using a hard roller of 50-100 durometer hardness, thus avoiding the need for thermal annealing. Optionally, a maximum distance from any location in the transparent top electrode to a nearest nanowire in the network is in the range between 1 to 20 microns. Optionally, a maximum distance from any location in the transparent top electrode to a nearest nanowire in the network is in the range between 1 to 10 microns. Optionally, a maximum distance from any location in the transparent top electrode to a nearest nanowire in the network is in the range between 2 to 5 microns. Optionally, the transparent top electrode without the nanowires has an electrical resistance of at least about 500 ohms per square or more. Optionally, the transparent top electrode without the nanowires has an electrical resistance of at least about 300 ohms per square or more. Optionally, the method comprises sputtering the transparent top electrode material over the nanowires. Optionally, the nanowires are randomly oriented. Optionally, the nanowires are coupled to the transparent top electrode using pressure, without an annealing step. Optionally, the nanowires are coupled to the transparent top electrode without heating above 150 C. Optionally, the nanowires are coupled to the transparent top electrode without heating above 100 C. Optionally, light transmission through the top electrode with the network layer of nanowires is at least 90% light transmission. Optionally, the combined electrical resistivity of the nanowire layer and the reduced thickness layer is about 10 ohms per square or less. Optionally, the combined electrical resistivity of the nanowire layer and the reduced thickness layer is about 5 ohms per square or less with at least 90% light transmission. Optionally, the combined electrical resistivity of the nanowire layer and the reduced thickness layer is about 4 ohms per square or less with at least 80% light transmission. Optionally, the combined electrical resistivity of the nanowire layer and the reduced thickness layer is about 3 ohms per square or less with at least 80% light transmission. Optionally, the combined electrical resistivity of the nanowire layer and the reduced thickness layer is about 2 ohms per square or less with at least 80% light transmission. Optionally, the combined electrical resistivity of the nanowire layer and the reduced thickness layer is about 1 ohms per square or less with at least 70% light transmission.

In another embodiment of the present invention, a method is provided comprising forming a photovoltaic absorber layer and a junction partner layer; forming a hybrid transparent conductive layer of a first thickness, the layer comprising: an isotropic layer for gathering charge from the junction partner layer; a nanowire network layer in contact with the isotropic layer. The hybrid transparent conductive layer increases overall photovoltaic efficiency of the cell compared to a cell using only a) an isotropic layer of a thickness equal to the first thickness or b) a nanowire network layer of thickness equal to the first thickness.

It should be understood that for any of the embodiments herein, the following may optionally also apply. Optionally, the hybrid transparent conductive layer has a thickness of 50 nm or less and is thinner than usual transparent top electrode, wherein the hybrid transparent conductive layer without the nanowires has an electrical resistance greater than 200 ohms per square. Optionally, the hybrid transparent conductive layer without the nanowires has an electrical resistance greater than 300 ohms per square. Optionally, the hybrid transparent conductive layer without the nanowires has an electrical resistance greater than 400 ohms per square. Optionally, the hybrid transparent conductive layer without the nanowires has an electrical resistance greater than 500 ohms per square. Optionally, the hybrid transparent conductive electrode has at least a light transmission of at least 90 percent in the visual spectrum. Optionally, the nanowires are coated onto the solar cell and subsequently pressed into it using a hard roller of 85 durometer hardness, thus avoiding the need for thermal annealing. Optionally, the isotropic layer is conformal to an upper surface of the absorber layer. Optionally, the isotropic layer has at least a bottom surface in conformal contact with an upper surface of the absorber layer so that the isotropic layer can gather charge from the absorber layer. Optionally, the nanowire layer has sufficient spacing between nanowires so as to be substantially transparent in wavelengths between about 400 nm to 800 nm. Optionally, the nanowire layer has sufficient spacing between nanowires so as to be substantially transparent in wavelengths between about 400 nm to 700 nm. It should be understood that light transmission as used herein refers to transmission in the visual spectrum. Optionally, the isotropic layer comprises a sol-gel layer.

In yet another embodiment of the present invention, a solar cell is provided comprising: a photovoltaic absorber layer; a hybrid transparent conductive layer of a first thickness, the layer comprising: an isotropic layer for gathering charge from the absorber layer, the isotropic layer having a minimal thickness creating a high sheet resistance of at least 500 ohms per square; a nanowire layer in contact with the isotropic layer; the nanowires layer having a pitch between about 1 microns to about 10 microns; wherein the hybrid layer increases overall power output of the cell compared to an otherwise identical cell using only a) an isotropic layer of a thickness equal to the first thickness or b) a nanowire layer of thickness equal to the first thickness.

Examples of solution deposition methods for an ink or dispersion of nanowires may include at least one method from the group comprising: wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink jet printing, jet deposition, spray deposition, aerosol spray deposition, dip coating, web coating, microgravure web coating, or combinations thereof. These applications of nanowires provide new avenues to lower costs, better durability, better thermal stability, and higher efficiencies. Of course, other non-solution based techniques may also be used.

In yet another embodiment of the present invention, a solar cell formed using binderless deposition of nanowires improve reliability of the cell in a laminate packaging (eg. panel package) by providing avoidance of destruction through shear forces by avoiding the binder.

In yet another embodiment a solar cell with a thinner than usual transparent top electrode that is coated with (silver or other metal) nanowires (in a binder or not), where the nanowires are coated plainly (in a solvent only; no binder) and subsequently overcoated with a binder. Optionally, the nanowires are coated onto the solar cell and subsequently pressed into it using a hard roller such as but not limited to an 85 durometer hardness, thus avoiding the need for thermal annealing. This allows the nanowires to connect it works just by pressing them if one does not coat them in a binder and if the roller is of sufficient hardness. In one embodiment, this provides a composite cell stack of an ultra-thin iZO/AZO layer combined with the Ag nanowire layer on top as a new top electrode of a solar cell.

A further understanding of the nature and advantages of the invention will become apparent by reference to the remaining portions of the specification and drawings.

### BRIEF DESCRIPTION OF THE DRAWINGS

FIG. 1 shows a cross-sectional view of a photovoltaic device according to one embodiment of the present invention.

FIG. 2A shows an image of nanowires according to one embodiment of the present invention.

FIGS. 2B-2D show various stacks according to embodiments of the present invention.

FIGS. 2E-2H show various views of nanowires in the device stack according to embodiments of the present invention.

FIG. 3A-3C shows cross-sectional views of devices formed using embodiments of methods according to the present invention.

FIG. 4A and 4B show cross-sectional and top down views of photovoltaic devices according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Device Stack

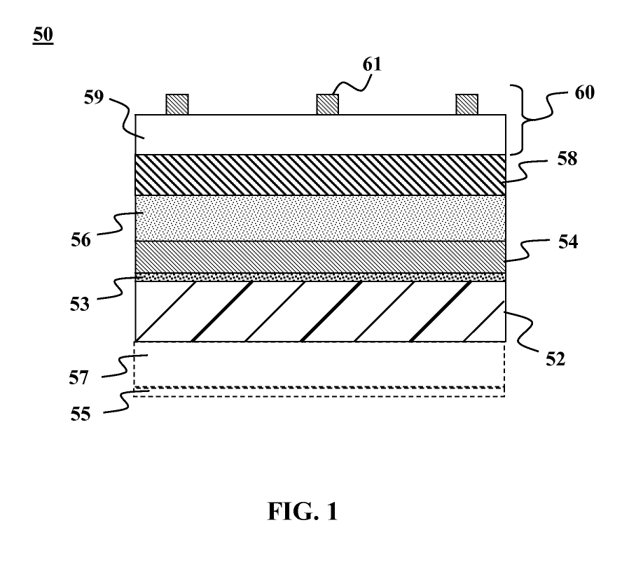

Referring now to FIG. 1, one example of a photovoltaic device is shown. The device 50 includes a base substrate 52, an optional adhesion layer 53, a base or back electrode 54, a p-type absorber layer 56, an n-type semiconductor thin film 58 and a transparent electrode 60. By way of example, the base substrate 52 may be made of a metal foil, a polymer such as polyimides (PI), polyamides, polyetheretherketone (PEEK), Polyethersulfone (PES), polyetherimide (PEI), polyethylene naphtalate (PEN), Polyester (PET), related polymers, a metallized plastic, and/or combination of the above and/or similar materials. By way of nonlimiting example, related polymers include those with similar structural and/or functional properties and/or material attributes. The base electrode 54 is made of an electrically conductive material. By way of example, the base electrode 54 may be of a metal layer whose thickness may be selected from the range of about 0.1 micron to about 25 microns. An optional intermediate layer 53 may be incorporated between the electrode 54 and the substrate 52. The transparent electrode 60 may include a transparent conductive layer 59 and a layer of metal (e.g., Al, Ag, Cu, or Ni) fingers 61 to reduce sheet resistance. Optionally, the layer 53 may be a diffusion barrier layer to prevent diffusion of material between the substrate 52 and the electrode 54. The diffusion barrier layer 53 may be a conductive layer or it may be an electrically nonconductive layer. As nonlimiting examples, the layer 53 may be composed of any of a variety of materials, including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing. Although not limited to the following, the thickness of this layer can range from 10 nm to 50 nm. In some embodiments, the layer may be from 10 nm to 30 nm. Optionally, an interfacial layer may be located above the electrode 54 and be comprised of a material such as including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing. The transparent conductive layer 59 may be inorganic, e.g., a transparent conductive oxide (TCO) such as but not limited to indium tin oxide (ITO), fluorinated indium tin oxide, zinc oxide (ZnO), Mg—ZnO, Li2O—ZnO, Zr—Zno, aluminum doped zinc oxide (AZO), gallium doped zinc oxide (GZO), boron doped zinc oxide (BZO).

Aluminum and molybdenum can and often do inter-diffuse into one another, with deleterious electronic and/or optoelectronic effects on the device 50. To inhibit such inter-diffusion, an intermediate, interfacial layer 53 may be incorporated between the aluminum foil substrate 52 and molybdenum base electrode 54. The interfacial layer may be composed of any of a variety of materials, including but not limited to chromium, vanadium, tungsten, and glass, or compounds such as nitrides (including but not limited to titanium nitride, tantalum nitride, tungsten nitride, hafnium nitride, niobium nitride, zirconium nitride vanadium nitride, silicon nitride, or molybdenum nitride), oxynitrides (including but not limited to oxynitrides of Ti, Ta, V, W, Si, Zr, Nb, Hf, or Mo), oxides, and/or carbides. The material may be selected to be an electrically conductive material. In one embodiment, the materials selected from the aforementioned may be those that are electrically conductive diffusion barriers. The thickness of this layer can range from 10 nm to 50 nm or from 10 nm to 30 nm. Optionally, the thickness may be in the range of about 50 nm to about 1000 nm. Optionally, the thickness may be in the range of about 100 nm to about 750 nm. Optionally, the thickness may be in the range of about 100 nm to about 500 nm. Optionally, the thickness may be in the range of about 110 nm to about 300 nm. In one embodiment, the thickness of the layer 53 is at least 100 nm or more. In another embodiment, the thickness of the layer 53 is at least 150 nm or more. In one embodiment, the thickness of the layer 53 is at least 200 nm or more. Optionally, some embodiments may include another layer such as but not limited to an aluminum layer above the layer 53 and below the base electrode layer 54. This layer may be thicker than the layer 53. Optionally, it may be the same thickness or thinner than the layer 53. This layer 53 may be placed on one or optionally both sides of the aluminum foil (shown as layer 55 in phantom in FIG. 1).

If barrier layers are on both sides of the aluminum foil, it should be understood that the protective layers may be of the same material or they may optionally be different materials from the aforementioned materials. The bottom protective layer 55 may be any of the materials. Optionally, some embodiments may include another layer 57 such as but not limited to an aluminum layer above the layer 55 and below the aluminum foil 52. This layer 57 may be thicker than the layer 53 (or the layer 54). Optionally, it may be the same thickness or thinner than the layer 53 (or the layer 54). Although not limited to the following, this layer 57 may be comprised of one or more of the following: Mo, Cu, Ag, Al, Ta, Ni, Cr, NiCr, or steel. Some embodiments may optionally have more than one layer between the protective layer 55 and the aluminum foil 52. Optionally, the material for the layer 55 may be an electrically insulating material such as but not limited to an oxide, alumina, or similar materials. For any of the embodiments herein, the layer 55 may be used with or without the layer 57.

The nascent absorber layer 56 may include material containing elements of groups IB, IIIA, and (optionally) VIA. Optionally, the absorber layer copper (Cu) is the group IB element, Gallium (Ga) and/or Indium (In) and/or Aluminum may be the group IIIA elements and Selenium (Se) and/or Sulfur (S) as group VIA elements. The group VIA element may be incorporated into the nascent absorber layer 56 when it is initially solution deposited or during subsequent processing to form a final absorber layer from the nascent absorber layer 56. The nascent absorber layer 56 may be about 1000 nm thick when deposited. Subsequent rapid thermal processing and incorporation of group VIA elements may change the morphology of the resulting absorber layer such that it increases in thickness (e.g., to about twice as much as the nascent layer thickness under some circumstances).

Fabrication of the absorber layer on the aluminum foil substrate 52 is relatively straightforward. First, the nascent absorber layer is deposited on the substrate 52 either directly on the aluminum or on an uppermost layer such as the electrode 54. By way of example, and without loss of generality, the nascent absorber layer may be deposited in the form of a film of a solution-based precursor material containing nanoparticles that include one or more elements of groups IB, IIIA and (optionally) VIA. Examples of such films of such solution-based printing techniques are described e.g., in commonly-assigned U.S. patent application Ser. No. 10/782,017, entitled “SOLUTION-BASED FABRICATION OF PHOTOVOLTAIC CELL” and also in PCT Publication WO 02/084708, entitled “METHOD OF FORMING SEMICONDUCTOR COMPOUND FILM FOR FABRICATION OF ELECTRONIC DEVICE AND FILM PRODUCED BY SAME” the disclosures of both of which are incorporated herein by reference.

In the present embodiment, layer 58 may be an n-type semiconductor thin film that serves as a junction partner between the compound film and the transparent conducting layer 59. By way of example, the n-type semiconductor thin film 58 (sometimes referred to as a junction partner layer) may include inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, e.g., by chemical bath deposition (CBD) and/or chemical surface deposition (and/or related methods), to a thickness ranging from about 2 nm to about 1000 nm, more preferably from about 5 nm to about 500 nm, and most preferably from about 10 nm to about 300 nm. This may also be configured for use in a continuous roll-to-roll and/or segmented roll-to-roll and/or a batch mode system.

The transparent conductive layer 59 may be inorganic, e.g., a transparent conductive oxide (TCO) such as but not limited to indium tin oxide (ITO), fluorinated indium tin oxide, zinc oxide (ZnO) or aluminum doped zinc oxide, or a related material, which can be deposited using any of a variety of means including but not limited to sputtering, evaporation, chemical bath deposition (CBD), electroplating, sol-gel based coating, spray coating, chemical vapor deposition (CVD), physical vapor deposition (PVD), atomic layer deposition (ALD), and the like. Alternatively, the transparent conductive layer may include a transparent conductive polymeric layer, e.g. a transparent layer of doped PEDOT (Poly-3,4-Ethylenedioxythiophene), nanowires or related structures, or other transparent organic materials, either singly or in combination, which can be deposited using spin, dip, or spray coating, and the like or using any of various vapor deposition techniques. Optionally, it should be understood that intrinsic (non-conductive) i-ZnO may be used between CdS and Al-doped ZnO (AZO). Combinations of inorganic and organic materials can also be used to form a hybrid transparent conductive layer. Thus, the layer 59 may optionally be an organic (polymeric or a mixed polymeric-molecular) or a hybrid (organic-inorganic) material. Examples of such a transparent conductive layer are described e.g., in commonly-assigned US Patent Application Publication Number 20040187317, which is incorporated herein by reference.

Those of skill in the art will be able to devise variations on the above embodiments that are within the scope of these teachings. For example, it is noted that in embodiments of the present invention, portions of the IB-IIIA precursor layers (or certain sub-layers of the precursor layers or other layers in the stack) may be deposited using techniques other than particle-based inks For example precursor layers or constituent sub-layers may be deposited using any of a variety of alternative deposition techniques including but not limited to solution-deposition of spherical nanopowder-based inks, vapor deposition techniques such as ALD, evaporation, sputtering, CVD, PVD, electroplating and the like.

### Hybrid Transparent Conductors

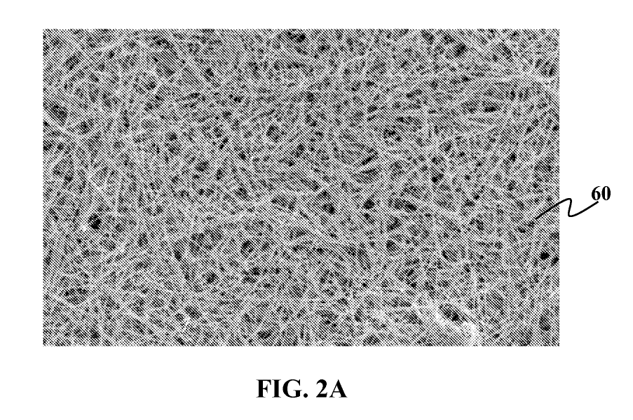

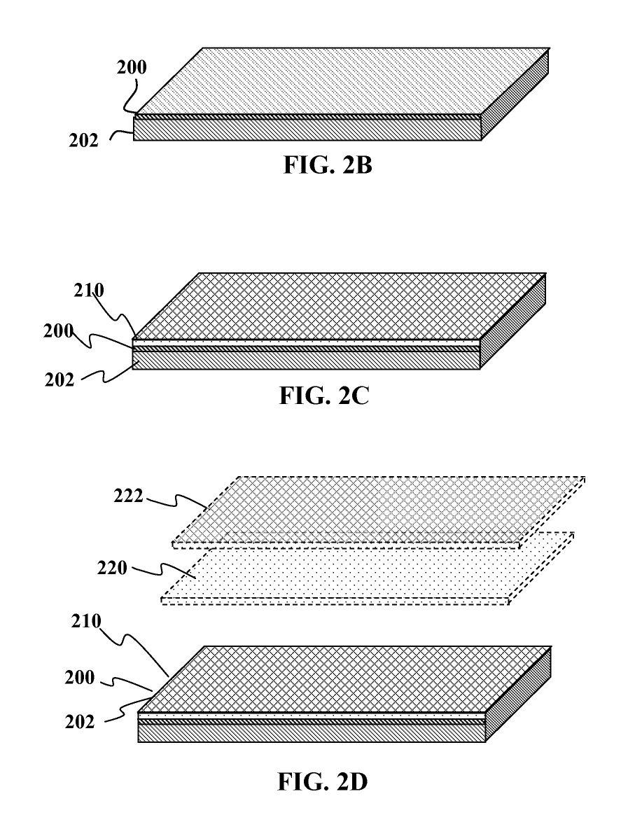

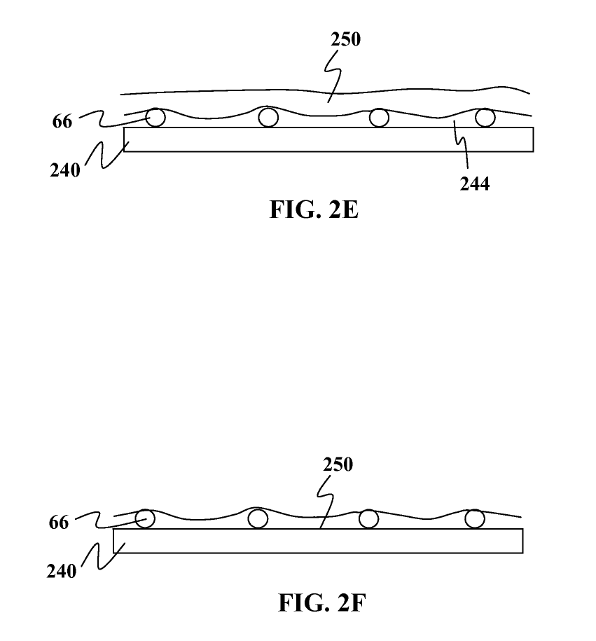

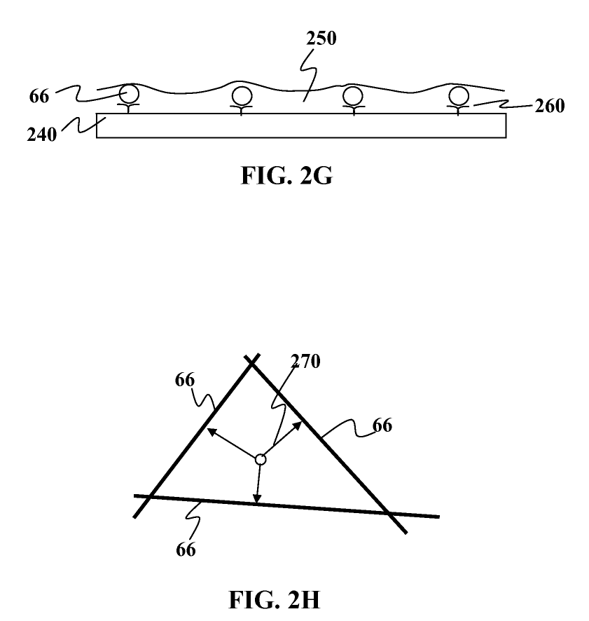

Referring now to FIG. 2A, another embodiment of the present invention will now be described. This embodiment of the present invention shows that the material in the transparent electrode layer 59 may be replaced with a non-traditional transparent electrode that includes a material such as, but not limited to, electrically conductive nanowires 66 as shown in the top down view of FIG. 2A. The nanowires 66 may be comprised of one or more materials selected from a variety of electrically conductive materials such as but not limited to Cu, Ag, Au, Ni, Al, Zn, Mo, Cr, W, Ta, metallic alloys, or the like.

As seen in FIG. 2A, a network of nanowires 66 may be formed by a variety of deposition techniques. In one embodiment, the nanowires may be from 20-30 microns in length with diameters of 10 nm to 100 nm. Of course, other sizes and shapes may also be used. A nanowire ink or dispersion may be formed for solution depositing the nanowires 66 onto a material. In one embodiment, the nanowire dispersion or ink may be formed using material viscosity modifiers or binders such as hydroxypropyl methyl cellulose (HPMC), methyl cellulose, xanthan gum, polyvinyl alcohol, carboxy methyl cellulose, or hydroxylethyl cellulose. In one embodiment, this may be in a substantially aqueous solution of about 99% wt or higher percent of water with a loading of nanowires between about 0.2 to 1% wt. Optionally, the nanowires loading may be in the range of about 0.25 to 0.75% wt. Optionally, the nanowires loading may be in the range of about 0.25 to 0.40% wt. The balance may be made of material such as HPMC and some embodiments may optionally include a surfactant such as a fluorsurfactant or the like. Silver and copper nanowires have been synthesized using a scalable method of AC electrodeposition into porous aluminum oxide templates, which produces gram quantities of metal nanowires ca. 25 nm in diameter and up to 5 and 10 micons in length for Ag and Cu, respectively. Electrical resistivity measurements performed on polymer nanocomposites containing different volume fractions of metal indicate that low percolation thresholds of nanowires are attained between compositions of 0.25 and 0.75 vol %.

In one embodiment, the network of nanowires or nanoparticles formed will be a perculating network. Below a certain nanowire concentration (also referred as the percolation threshold), the conductivity from one end of the layer to the other is zero, i.e. there is no continuous current path provided because the nanowires are spaced too far apart. Above this concentration, there is at least one current path available. As more current paths are provided, the overall resistance of the layer will decrease as more continuous paths are created. Percolation threshold is a mathematical term related to percolation theory, which is the formation of long-range connectivity in random systems. In engineering and coffee making, percolation is the slow flow of fluids through porous media, but in the mathematics and physics worlds it generally refers to simplified lattice models of random systems, and the nature of the connectivity in them. The percolation threshold is the critical value of the occupation probability p, or more generally a critical surface for a group of parameters p1, p2, . . . , such that infinite connectivity (percolation) first occurs.

The most common percolation model is to take a regular lattice, like a square lattice, and make it into a random network by randomly “occupying” sites (vertices) or bonds (edges) with a statistically independent probability p. At a critical threshold pc, long-range connectivity first appears, and this is called the percolation threshold. More general systems have several probabilities p1, p2, etc., and the transition is characterized by a critical surface or manifold. One can also consider continuum systems, such as overlapping disks and spheres placed randomly, or the negative space (Swiss-cheese models). A variety of percolation networks may be used herein such as but not limited to: 2d regular and Archimedean lattices; 2-Uniform Lattices; 2d bowtie and martini lattices; other 2d lattices; subnet lattices; polymers (random walks) on a square lattice; self-avoiding walks of length k added by random sequential adsorption; 2d inhomogeneous lattices; 2d continuum models; 2d random and quasi-lattices; 3d lattices; 3d continuum models; hypercubic lattices; and/or kagomé lattices in higher dimensions.

One or more connection techniques may be used to couple the nanowires in the network together. Some embodiments may use heat such as annealing while others use pressure such as through rollers to force the nanowires into contact.

Referring now to FIG. 2B, one embodiment of the present invention will now be described. In the present embodiment, a very thin layer of transparent conductive material 200 is deposited over the absorber layer 202. For ease of illustration, other layers of the stack below the absorber layer 202 such as the junction partner layer or other overlying layer are not shown. In one nonlimiting example, this very thin layer of transparent conductive material 200 may have a thickness of about 50 nm of aluminum doped zinc oxide or less. Optionally, the thickness may be about 75 nm or less of transparent conductive material. Optionally, the thickness may be about 100 nm or less of transparent conductive material. Optionally, the thickness may be about 150 nm or less of transparent conductive material. Optionally, the thickness may be about 200 nm or less of transparent conductive material. Optionally, the thickness may be much thinner, in the range of 40 nm or less of transparent conductive material. Optionally, the thickness may be much thinner, in the range of 30 nm or less of transparent conductive material. Optionally, the thickness may be much thinner, in the range of 20 nm or less of transparent conductive material. Optionally, the thickness may be much thinner, in the range of 10 nm or less of transparent conductive material. Optionally, the thickness may be less than 50% of the thickness of a transparent conductive material typically used for such applications. Optionally, the thickness may be less than 0.25 of the thickness of a transparent conductive material typically used for such applications. This layer serves as an isotropic conductive layer which provides conformal 2 dimensional (2-D) coverage on the underlying absorber and conducts electricity from the absorber in vertical or z-direction. It should be understood that a variety of materials such as but not limited to ITO, AZO, i-AZO, or the like may be used for this transparent conductive layer.

Then, in the present nonlimiting example, FIG. 2C shows a 2-D network of nanotubes, nanowires, or other open patterned layer 210 is deposited on top of the conductive material. Optionally, it should be understood that some embodiments may reverse the process and deposit the layer 210 first and then sputter TCE or TCO material on top of the layer 210. Deposition may occur by any variety of methods including but not limited to solution deposition, slot die deposition, vacuum deposition, or the like. This network layer 210 serves as electrical conduction highways which transports the collected current from underneath transparent layer. The porosity of conductive nanotubes or nanowires network could be tuned to sustain or allow a high sheet resistance conductive connecting-layer so that the resistive loss for two-dimensional current transport in the connecting-layer to its nearest nanotube or nanowire is negligible. With this approach, the present embodiment is able to harvest higher photo current and hence achieve higher efficiency compared to cells with sputtered TCO electrode. In one example, the 2-D network of nanowires comprises of 50 nm thick carbon nanotubes. Optionally, the 2-D network comprises of a 50 nm to 100 nm thick layer of carbon nanotubes. Optionally, the 2-D network comprises of a 30 nm to 150 nm thick layer of carbon nanotubes. Optionally, the 2-D network comprises of a 10 nm to 200 nm thick layer of carbon nanotubes. In another nonlimiting example, the 2-D network of nanowires comprises of 50 nm thick silver nanowires. Optionally, the 2-D network comprises of a 50 nm to 100 nm thick layer of electrically conductive nanowires. Optionally, the 2-D network comprises of a 30 nm to 150 nm thick layer of electrically conductive nanowires. Optionally, the 2-D network comprises of a 10 nm to 200 nm thick layer of electrically conductive nanowires. Of course, other electrically conductive materials may also be used in place of silver, carbon, or other materials to form the desired percolating network.

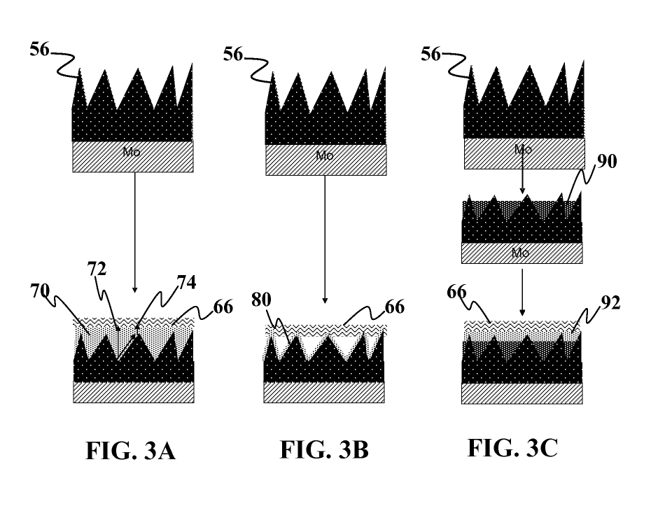

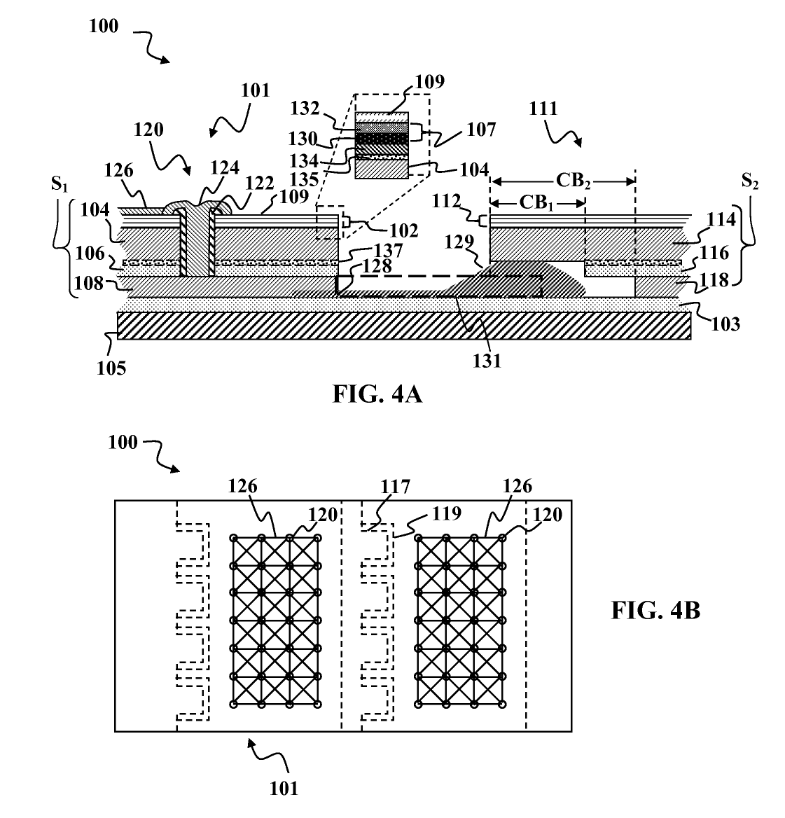

It should be understood that the reduced thickness of the conformal layer 100 due to the use of layer 210 allows for more light to pass through and be absorbed by the underlying absorber layer. The pitch of the open network layer 210 is selected to be substantially transparent for the optical wavelengths. Embodiments of the present invention also provides improved surface contact due to the layer 210 which helps to reduce the roughness of the underlying absorber layer as seen in FIG. 3. This improved contact will allow the conductive fingers shown in FIG. 4 to have better electrical contact and reduced resistance due to greater surface contact provided by layer 210.

Referring still to FIG. 2C, it should be understood that the structure of the nanotubes and/or nanowires may also be varied. In one embodiment, the nanotubes or nanowires may have diameters of between about 30 nm to about 100 nm. Optionally, they may have diameters between about 40 nm to about 80 nm. The length of the nanotubes or nanowires may be in the range of about 10 to about 100 microns. Optionally, the length of the nanotubes or nanowires may be in the range of about 20 to about 150 microns. Optionally, the length of the nanotubes or nanowires may be in the range of about 30 to about 200 microns.

Referring now to FIG. 2D, it should also be understood that there may be other layers of material deposited over the layer 200 and 210. FIG. 2D shows that another layer 220 similar to layer 200 may also be deposited over the open patterned layer 210. Another open pattern layer may be deposited over layer 220. In some embodiments, both the layers 220 and 222 are open pattern layers. Optionally, both layers are conformal layers such as layer 200. These layers 220 and 222 may be thinner than layers 200 and 210. Optionally, one of the layers 220 and 222 may be thicker than any of the underlying layers.

In some embodiments, there may be a gradation of nanowires to microwires in the various layers over the absorber layer. In one nonlimiting embodiment, the nanowires have a diameter in the nanoscale. In one embodiment, the open pattern layer may have nanowires or nanotubes between 10 nm to about 100 nm in diameter. They may be at a pitch of about 2 to about 5 microns. The next layer may have nanotubes or nanowires at a next thickness such as but not limited to a thickness of about 100 nm to about 1000 nm in diameter. Although still forming a network, the pitch will be greater, leaving more open space between nanowires and nanotubes. The pitch may be 1.5 to 5 times that of the underlying layer. There may be a still further layer comprised of microwires with diameters about 1 micron or more. The pitch may be 1.5 to 5 times that of the underlying layer.

It should be understood that the layer 210 may be conformal to the layer 200. Optionally, depending on the thickness of the nanotubes or nanowires, some may be a discrete, nonconformal layer over the layer 200. In one nonlimiting example, this layer 210 may be solution deposited over the layer 100 so that diluting the solution will increase the pitch as the nanowires or nanotubes become more distributed in the liquid. Some embodiments, in the solution deposition step, may include binders in the solution of nanowires or nanotubes. Other embodiments may deposit the open pattern layer without the use of binders and/or solvents.

In another embodiment of this invention, one or more of these conductive layers could be deposited by non-vacuum based methods, which generally are of high throughput and lower cost.

In another embodiment of this invention, the openness or pitch of the nanotubes or nanowire network can be tuned such that higher sheet resistance (>500 ohm/sq) conductive connecting-layer could be used. Optionally, some embodiments may use higher sheet resistance (>600 ohm/sq) conductive connecting-layer. Optionally, some embodiments may use higher sheet resistance (>700 ohm/sq) conductive connecting-layer. Optionally, some embodiments may use higher sheet resistance (>800 ohm/sq) conductive connecting-layer. Optionally, some embodiments may use higher sheet resistance (>900 ohm/sq) conductive connecting-layer. Optionally, some embodiments may use higher sheet resistance (>1000 ohm/sq) conductive connecting-layer. It should be understood that the connecting-layer may be an under layer, an over layer, or both.

Another element of one embodiment of the present invention is that the diameter of nanowires is substantially smaller than the wavelengths of light being absorbed for photocurrent generation.

The isotropic conductive connecting-layer which collects current from absorber layer could be made of any conductive metal oxides (e.g. ITO, ZnO, SnO etc), conductive polymers (PEDOT, polyaniline, polypyrrole etc.) or combination of both.

The electrical conductive under-layer could be sputtered, solution coated or by low-temperature conversion of precursors (nanoparticles, sol-gels).

Both the conductive connecting-layer and nanowire network could be applied sequentially or simultaneously.

Furthermore, for solution processing, one could pre-mix the nanowires with the connecting-layer precursor materials, then apply on top of the CIGS/CdS. Instead of having two distinctive layers, one could also have a composite layer with nanowires embedded in a high sheet resistance conductive matrix.

Finally, one could also first lay down the nanowire network and then overcoat the network and fill the gap between nanowires with transparent conductive materials (ITO particles, TCO precursors or conductive polymers). A low temperature annealing step might be needed to improve the sheet conductivity and minimize the contact resistance.

In another embodiment of this invention, the electrical transport layer consists of one or more layers of conductive materials/nanowires that serve to transport electrical current for the adsorber layers (CIGS/CdS or CdTe). By way of nonlimiting example, two ways of getting the nanowires to connect: annealing is standard . . . but it should be understood that the connection of nanowires works just by pressing them if one does not coat them in a binder . . . if the roll is a hard one.

Example 1: using a conductive sol gel coating with nanowires therein to create the hybrid transparent conducting layer.

Example 2: depositing a layer of nanowires or nanotubes without any binder and then vacuum depositing and/or solution depositing a conformal layer 100 over the layer of nanowires or nanotubes to act as a binder and conformal charge collection layer.

Example 3: depositing a layer of nanowires or nanotubes without any binder and that layer is then pressed to connect the nanowires. There may or may not be an underlying layer 100. Some embodiments may deposit a layer 100 after the nanowire layer 110 is first deposited.

Nanowires 66 and/or other conductive fibrous materials can provide electrical conductance at packing densities that provide partial optical transparency. In some embodiments, the nanowires 66 may deposited at a preselected pitch which will control the density of the coating. Optionally, the layer has very little absorbance in the spectral range from about 400 nm to about 1100 nm. As seen in FIG. 2A, the nanowires 66 when deposited resemble a fibrous or web-like covering. It should be understood that the fibrous conductor may be used with or without i-ZnO. Besides nanowires, other suitable materials may also be used for a printable transparent conductor. Some embodiments may comprise of metal-based nanoassembled layers that are suitable as transparent conductors. These materials may also be fibrous in nature.

A spectrum of techniques and device constructions may be used for applying these materials to the fabrication of low-cost, long-lived thin-film solar cells, in particular cells constructed on low-cost metal foils, including cells fashioned in an emitter wrap-through structure. Examples of suitable solution deposition methods may include at least one method from the group comprising: wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink-jet printing, jet deposition, spray deposition, aerosol spray deposition, dip coating, web coating, microgravure web coating, or combinations thereof. These applications of nanowires provide new avenues to lower costs, better durability, better thermal stability, and higher efficiencies. Of course, other non-solution based techniques may also be used.

Although promising, the work on replacing the known transparent electrode is not without challenges in terms of process ease or expense. The cell performance may be worse (low shunt resistance) when the nanowires layer 66 is used in conjunction with printable CIGS on glass with evaporated selenium/RTP selenization and thin i-ZnO. Upon further investigation, one reason for the shunting is because the absorber layer 56 is too rough to be protected by the i-ZnO and the electrical properties may not be suited for further protection like those of the ZnO:Al are.

To address some of these issues, one embodiment of the present invention may address the issue by designing a smoother interface with the transparent conductor layer. This may involve adjusting or modifying the substrate on which the absorber layer 56 is formed or other techniques. By modifying the underlying layer, this results in an absorber layer 56 that is smoother without actually adding additional surface treatment to the absorber layer 56 itself. If the absorber layer 56 is sufficiently smooth, then the shunting issue would be minimized and a number of various materials may be used to provide the insulation desired at that interface. Examples of layers that can be deposited before the layer of nanowires layer 66 in this case are insulating polymers deposited by standard solution coatings, polyelectrolytes deposited via dip casting or a bath technique, sol gels resulting in inorganic or metal-organic layers, or similar materials.

Referring now to FIG. 2E, a side cross-sectional view of a top layer of a solar cell according to the present invention will now be described. This embodiment shows that a layer 240 that may be a junction partner layer such as but not limited to a CdS layer, other II-VI material, or the like. Optionally, the layer 240 may be a layer such as but not limited to i-ZnO or other oxide material (doped or undoped). FIG. 2E shows that the nanowires 66 may be arranged to be located on layer 240 at random locations. In one embodiment, a binder layer 244 may be used hold the nanowires 66 in position. A transparent conductive material layer 250 may be deposited over and/or under the nanowires 66. In the embodiment of FIG. 2E, the layer 250 of transparent conductive material layer 250 is deposited over the nanowires 66.

Referring now to FIG. 2F, a binderless embodiment is shown wherein the nanowires 66 are directly encased in the layer 250 of the transparent conductive material. In one embodiment, a higher viscosity solvent such as one with greater than 100 CPS may be used as the solvent to minimize movement of nanowires during drying. This allows for greater surface contact between the nanowires 66 and the layer 250 since the layer 250 will be able to surround the nanowires 66 more directly. In the embodiments that use binders, the nanowires 66 will inherently lose some surface area due to contact or coverage by the binder. The binderless embodiments may be created by depositing the nanowires in solvent only without binders on to the targeted layers.

Referring now to FIG. 2G, some embodiments may functionalize the underlying layer 240 so that there are receptor areas 260 on the layer 240 which are receptive to or create improved contact with the nanowires 66 to hold them in position until the layer 250 is deposited over the nanowires 66 as seen in FIG. 2F. In one nonlimiting example, the layer 240 may be a thin layer 240 of ITO which is modified with 16-Mercaptohexadecanoic (MHDA) acid theron where there is strong interaction between the silver nanowires and the —SH end 260 of the funcitionalized layer. The —OH end of the chain is in contact with the layer 240 while the —SH end is positioned distal from the layer to attract silver nanoparticles or nanowires. Of course, similar materials to 16-Mercaptohexadecanoic acid or other materials with ligand or groups that attract silver or other material of the nanowires may be used to treat the substrate or layer on which the nanowires will be coated.

Referring now to FIG. 2H, a top down view is shown of a portion of the nanowires 66 over the solar cell. This figure is provided to show that there is a maximum distance 270 to the nearest nanowires and that the system may be configured so that the layer 250 may have a sheet resistance that allow current to travel to the nearest nanowires 66 while still being thinner and less costly than those used in embodiments without the nanowires network.

### Roughness

Referring now to FIGS. 3A through 3C, other embodiments of the present invention with rough absorber layers 56 may use one or more layers or surface treatments to compensate for the roughness. In some embodiments, the surface treatments may be directed at the insulating layer that would be substituting for the i-ZnO. For ease of illustration, the junction partner 58 is now shown in FIGS. 3A and 3C. If shown, they may be a layer (conformal or not) directly above and in contact with layer 56.

Referring now to FIG. 3A, one embodiment of the present invention may comprise of coating the absorber layer 56 with an insulator 70 thick enough to cover all surfaces of the absorber layer 56. The web or mesh transparent conductor 66 would be positioned over this insulator 70. The insulator 70 prevents shunting in zero voltage situations. This could be done with the same candidates mentioned above or with thicker i-ZnO than normal. The thickness of such a layer 70 may be in the range of about 50 nm to about 1000 nm. Optionally, the thickness of layer 70 may be in the range of about 100 nm to about 500 nm. Optionally, the thickness of layer 70 may be in the range of about 150 nm to about 300 nm. In this embodiment, it is desirable if electrons in the absorber layer 56 can easily move out from the low spots in the absorber layer 56. This may be addressed by having an insulator 70 of minimal thickness so the electrons can move out directly up through the insulator (as indicated by arrow 72). Optionally, the absorber layer 56 is sufficiently conductive to allow the electron to find its way to the high spots of the absorber layer 56 (as indicated by arrows 74) and then move out through the thinner areas of the insulator 70.

Referring now to FIG. 3B, another approach is to lay down or coat a conformal insulator 80 before the transparent conductor layer. An insulator layer that conformally coats the surface will address the shunting issue and the electron mobility issue. The materials available for the conformal insulator 80 changes since the deposition technique will impact the type of materials that may be used. Some suitable techniques to obtain conformal layers include but are not limited to the following: CBD, ALD, (see old disclosures including the shunt protection disclosure). The list of materials will depend on the technique but alumina, silica, insulating polymers grown by layer-by-layer techniques are some of those. The resulting combinations of layers retain a certain degree of surface roughness, but due to the conformal coverage of insulator 80, the number of bare or uninsulated spots are minimized, which in turn minimizes shunting.

Referring now to FIG. 3C, yet another embodiment of the present invention addresses the shunting issue and electron mobility issue by depositing two layers over the rough absorber layer 56. By way of nonlimiting example, the two layers may comprise of a leveling conductive layer 90 and the insulator 92. The final approach (less preferred due to an extra step) is to fill the low spots with a conductor first. If the conductor is desirably as good as the ZnO:Al then the amount of nanowires can be minimized. Optionally, sol gel TCO, TCO particles, etc without the full sintering temperature may be suitable. Then the insulator can be coated on top before the nanowire layers.

In another embodiment of the present invention, the smoothness offered by the vapor selenium technique (on Al foil) will allow the nanowire layer 66 to behave properly without shunting. This embodiment involves the use of a nanowire layer on printed CIG with the conditions that give smooth CIGS. The use of a smoother underlying substrate such as the metal foil described will create a smoother absorber layer.

In yet another embodiment of the present invention, the use of the nanowires is likely to allow thinner ZnO:Al. This embodiment does not involve replacing ZnO:Al but using it in conjunction with the appropriate web-like conductor. ZnO:Al as thin as about 100 nm might be enough to stop shunting. Optionally, the layer of ZnO:Al may be about 100 to about 200 nm in thickness. Optionally, the layer of ZnO:Al may be about 100 to about 500 nm in thickness. nanowires may be formed on top of this layer (nanowires have no measurable “thickness”). Instead they are agglomerated and form particle monolayers. This saves time in sputtering and materials used for ZnO:Al. In one embodiment, the ZnO:Al may be below the nanowire or other web like layer. In one embodiment, the ZnO:Al may be above the nanowire or other web like layer.

### Alternative Embodiments

Optionally, the web-like transparent conductor layer is used in conjunction with ZnO:Al to make thinner ZnO:Al layers. By way of nonlimiting example, nanowires are used as a first layer and very thin metal oxide coating as an overlayer that provides mechanical cohesion (e.g. as a binder) of the underlying nanowire coating and provides top surface chemical durability for long service life. The thickness of the ZnO:Al layer may be in the range of about 50 nm to about 500 nm.

Optionally, in place of CdS and ZnO, a web-like transparent conductor may be used. The web-like transparent conductor may be bound by a suitable binder. A material such as ZnS, CdS, or ZnO may be used to provide a matrix wherein the web-like transparent conductor is used to improve the conductivity of the surrounding material (ZnS, CdS, or ZnO) used as the junction partner with the absorber layer.

Optionally, in conjunction with a binder to provide stability to the layer. The binder may be a conductive binder. The binder may be a material that is suitable as a junction partner with the absorber layer.

Optionally, using the same binder as a thin layer between the nanowire layer and CIGS/(CdS) to prevent shunting in place of i-ZnO.

Optionally, in conjunction with ALD deposited insulator, e.g. using an ALD top coating to provide both a binder function to the underlying nanowires and an environmental protection function vis-à-vis cell stability in the field

Optionally, in conjunction with an insulating binder or other overlayer to protect the device whereby electrical contact can only be made by penetrating the protective layer (with via for example)

Optionally, a web-like transparent conductor layer may be used with a metal wrap through (MWT) type solar cell. Further details of such an embodiment may be found with reference to FIG. 4. If used with an MWT solar, the following may apply:

a. A web-like transparent conductor layer may be used as the conductive transparent top coating of an emitter wrap through (MWT) cell structure, where a sheet resistance of about 10—about 1000 ohm/sq is used, optionally about 40—about 200 ohm/sq, or optionally about 50—about 100 ohm/sq

b. A web-like transparent conductor layer may be used as a conductive transparent top coating deposited on a MWT cell stack after the formation of insulated holes, serving thereby to provide both lateral sheet conductance and through-hole conductance.

c. A web-like transparent conductor layer may be used as a conductive transparent element providing better cell durability as a result of better thermal expansion matching and better adhesion to MWT materials of construction.

Note that an additional advantage with MWT might be related to the solution processibility in that hole punching might cause less damage to them or that they can be applied after the hole and used also as the wrap through conductor.

Optionally, a web-like transparent conductor layer may be used on CIGS cells made on metal foil (thus giving them the smoothness desired for complete insulator coverage)

Optionally, a web-like transparent conductor layer may be used to make layers or lines <0.01 ohm/sq

Optionally, a web-like transparent conductor layer may be used to make layers or lines ˜50 ohm/sq

Optionally, a web-like transparent conductor layer may be used to make layers or lines ˜200 ohm/sq for use with MWT technology.

Although ZnO:Al and i-ZnO are used above, it should be understood that their use is purely exemplary and more generally speaking, various “conductive TCO” and “insulating TCO” are suitable.

### TCE Qualities

Although not limited to the following, the conductivity desired for the transparent conductor on solar cells may be on the order of about 100 Ω/sq., optionally not more than about 200 Ω/sq., and optionally as low as about 10 Ω/sq or less, with very little absorbance in the spectral range from about 400 to about 1100 nm (the difference between actual and 100% transmittance should ideally be solely reflectance, which for the realized indices of refraction of TCO films is around 10-15%). ITO films, especially if deposited at temperatures of a few hundred C, can provide 20 Ω/sq with no absorbance; below that value the absorbance begins to be significant. Al:ZnO is similar though generally not as good. In both cases, the transmittance is around about 85-90% over most of the wavelength range.

One way to avoid the difficulties inherent in transparent oxides is to use very narrow lines of excellent metallic conductors, with wide open regions in between. To illustrate the performance of such an architecture, consider the resistance of an array of silver lines, 40 nm wide and 40 nm high. If 1000 such lines are placed in parallel, spaced 10 pm apart (so the array is 1 cm wide), the sheet resistance would be 100 Ω/sq., which is a useful range for solar cell electrodes. At the same time, the optical transmittance would be >99% (obscured area 0.4%).

Although not limited to the following, the synthesis of silver nanorods with diameters of about 35 nm (±5 nm) and lengths of several microns (up to 18 microns) has been described in the scientific literature (Cathy Murphy et al., Nanoletters, vol. 3, p. 667, 2003). The conductivity of these essentially single crystal nanorods is close to the bulk silver resistivity value of 1.6×10⁻⁶ Ωcm. Thus they would come within a factor of two or better of meeting the target of the hypothetical structure proposed above, if they could be connected in continuous lines and distributed with their axes parallel.

One method of making such connections is to simply line the rods up so that their ends are, on average, close to one another, and introduce a conducting medium in between. The conducting medium can be something of much lesser conductivity, such as AI:ZnO, for example. The result is a set of very low resistance resistors, several microns long, in series with high resistance resistors which are in general much shorter. The exact length of the high resistance elements depends on the method of orienting the rods. For example, flow orientation may be used: the rods are deposited in a linear coating flow, as typical of web coating. The extremely large aspect ratio of the rods assists in making them orient in the flow direction; polymers (later removed) can be used to refine this order.

If the rods align predominantly into columns in the direction of flow, as is expected, then the actual resistance of a chain may be only a few times the value of an ideal continuous chain. Alternatively, one may use capping techniques to attach functional end groups to the chains. It is known in the literature that reaction rates with ligands (typically organic or organometallic molecules) are sensitive to crystal facet, so that groups can be added preferentially to the rod ends and not to the sides. These groups can then be used to attach the rods into long chains.

Note that the actual effectiveness of such rods is greater than the simple calculation, in that the shadowing above was calculated assuming a square cross section. In fact the rods are round, and this means that light striking them will bounce off in a range of directions. If they are encased in a surrounding medium with some typical index of refraction in the range of 1.4-1.7, then rays with reflected angles greater than −55 deg. from the vertical will be totally internally reflected at the medium-air interface, and when they come down a second time they are unlikely to strike another Ag nanorod, and so will enter the solar cell absorber layer. Thus, careful choice of surrounding medium (specifically the dielectric whose upper surface is in contact with air) can allow up to a few percent blockage of light, and still be superior to existing solutions with respect to optical loss. This means that the rods can be closer than 10 um laterally, and this increases the probability of nanoscale separations between rod ends. The electrically connecting medium can be supplied by conventional means, such as sputtering, or by some solution technique.

Regarding the metallic materials: One possibility would be to use particles (or flakes) of relatively low-melting conductive material (preferably melting in a range of 150-250 C), and heat the layer (and substrate) to a temperature where the metallic material sinters with the other particles without damaging the underlying layers. Examples are Sn—Bi, Pb—Sn, Zn—Sn, Ag—Sn, and Al—Sn. Another possibility would be to use a mixture of at least two different types of metallic particles (or flakes) where one particle has an melting point below 150 C, preferably below 100 C, and where the heating results in the formation of a conductive alloy (solid-solution or line-compound) with a high melting-point, preferably far above 150 C. Examples are alloys with low-melting materials like Ga, Cs, Rb, and Hg combined with high-melting materials like Al, Cu, Fe, Ni, to form for example a Al—Ga solid-solution, Cu—Ga solid-solution or line-compound, etc.

Regarding method: A two-step deposition of low-organic-containing conductive material followed by a high-organic-containing mechanical stabilizer will improve both the morphology of the conductive matrix and enlarge the contact area between the conductive material and the underlying surface, if compression and/or heating need to be limited, and the top surface not necessarily is in direct contact with conductive material.

The process is preferably roll-to-roll, but use of rigid substrates is not excluded. Deposition methods include but are not limited to Roll-to-Roll Atomic Layer Deposition (R2R-ALD), Roll-to-Roll Chemical Vapor Deposition (R2R-CVD), Roll-to-Roll Lamination (R2R-lamination) of transparent conductive film, wet deposition via e.g. microgravure coating and spraying of soluble metal organic precursor. Some suitable in-line roll to roll techniques are described in U.S. patent application Ser. No. 10/782,233 filed Feb. 19, 2004 and fully incorporated herein by reference for all purposes.

Optionally, the transparent conductive electrode film may include materials; metals, conductive oxides, conductive nitrides, conjugated molecules, conjugated polymers, fullerenes, TCO particles, doped semiconductor particles (spheres, tetrapods, rods, wires), SOLDERS, Ga-AMALGAMS, TCO: AZO, GZO, BZO, ITO and the like.

Optionally, the material may be organo-metallic precursor containing either Al, Ga, and/or B & TCO particles.

Optionally, the method may include depositing molecularly dissolved or solid particles of organo-metallic precursors containing Zn, and dopants like Al, B, Ga, and/or other dopants, graphite sheets, the like, and/or combinations of the foregoing. Any of the techniques may be combined in single or multiple combinations of any other technique described herein.

Optionally, the method may include using ultrathin layer of metal (using techniques such as but not limited to electroless deposition, ALD, thermal decomposition of a solution-deposited soluble metal precursor, or the like), like Ti, Zn, Zr or the like providing metal contact between silver fingers and TCO, but oxidizing the unexposed metal via e.g. an atmospheric oxygen plasma will improve transparency; Cu, Sn, Hf, Ru.

Optionally, the method may include integrating traces/grids/fingers/lines with underlying TCE.

Typically in thin-film PV, Liquid Crystal Displays, Light emitting diodes, and other opto-electronic applications, the transparent conductive layer is a transparent conductive oxide deposited in slow expensive vacuum equipment. New lower-cost materials and lower-cost deposition methods that have been developed are solution-deposition of nanowires or metal nanowires that both result in a more or less random percolating network of conductive tubes/wires. Typically these networks are stabilized by co-deposition or over-coating with a polymer matrix. Relying on percolating networks, and therefore a combination of hopping conduction and conduction through the wires/tubes limits the conductivity and/or the transparency especially when both the transparency and the conductivity need to be increased simultaneously, such as that for layer 210 herein.

The present embodiment of the invention described here allows not only for an alternative method, but also for a better combined performance from both an electrical and optical point-of-view, meaning the invention allows for more facile and independent adjustment of conductivity (in all three dimensions) and optical properties (minimize optical losses).

The preferred method of creating a low-temperature curable transparent conductor is by solution deposition of transparent block-co-polymers combined with simultaneous or subsequent deposition of metal precursors that will fill the pores with a metal organized 3D-network. Depending on the type of block-co-polymers and chemistry used for the metallization of the porous highly organized block-co-polymer network, the filling of the pores can either be performed on top of the stack/substrate in the final product, or separately, and subsequently be transferred as a mechanically stable film to the final product followed by lamination. Filling the pores of the block-co-polymer structure can be performed by electro-deposition, electro-less deposition, like chemical bath deposition, chemical surface deposition, and horizontal bath deposition, spraying, solution coating, solution printing, etc. Similar precursors can be used as applied for wet chemical synthesis of metal nano-powders. Other deposition methods that can be used to fill the polymer network are atomic layer deposition, chemical vapor deposition, and the like.

Apart from filling the polymer network with metallic precursors that convert to metal, the porous polymer network can be filled with carbon black, fullerenes, metal nanopowder, transparent conductive oxide precursors (sol-gel), TCO nanopowder, or filled by vacuum deposition of TCO (or metal). The latter two examples (using vacuum deposition to fill a porous polymer network) would be particularly interesting when transferring a mechanically stable polymer film filled with conductive material to the final product, where the final product cannot withstand high temperatures and the curing of the polymer network with/without curing of the conductive network requires high temperatures.

One embodiment of the invention may comprise of high-efficiency thin-film solar cells based on polycrystalline CIGS (copper indium gallium di-selenide, but not excluding any other of the IB, IIIA, VIA elements like e.g. aluminum, and sulfur) are typically made with a transparent conductive oxide on top requiring additional conductive patterns to collect the current with minimal resistive losses. Lowering the cost of the deposition of these patterns is required to minimize the overall cost of the solar panels.

One major challenge to make highly-conductive patterns via solution-deposition is to be able to formulate an ink (slurry, paste, dispersion, emulsion, paint) that allows solution-deposition of conductive materials onto a substrate without the negative influence organic additives might have on the contact resistance to the substrate (being the transparent conductive oxide) and conductivity within the bulk of the pattern, since typically solution-deposited patterns rely on hopping conductance between particles thereby making the conductivity (but also the contact area for the conductive material in the two-phase patterns with the substrate) very sensitive to the morphology of the two-phase system of insulating-organic and conductive material. Additionally, subsequent heating (temperature and time) to mechanically stabilize these patterns and/or improve on contact resistance and/or improve on bulk-conductivity needs to be limited not to damage the underlying layers. Furthermore, the difference in the coefficient of thermal expansion between organic additives and the conductive component in the ink is typically large, which might cause difficulties during heating after solution-deposition or might limit the stability of these patterns over time.

In order to overcome the difficulties with typical inks used for solution-deposition, a new material and method is proposed in this invention disclosure.

Regarding materials: One embodiment uses particles (or flakes) of relatively low-melting conductive material (preferably melting in a range of 150-250 C), and heat the pattern (and substrate) to a temperature where the conductive material sinters without damaging the underlying layers. Examples include but are not limited to Sn—Bi, Pb—Sn, Zn—Sn, Ag—Sn, and Al—Sn. Another possibility would be to use a mixture of at least two different types of particles (or flakes) where one particle has an melting point below 150 C, preferably below 100 C, and where the heating results in the formation of a conductive alloy (solid-solution or line-compound) with a high melting-point, preferably far above 150 C. Examples are alloys with low-melting materials like Ga, Cs, Rb, and Hg combined with high-melting materials like Al, Cu, Fe, Ni, to form for example a Al—Ga solid-solution, Cu—Ga solid-solution or line-compound, etc.

Regarding method, one embodiment may use a two-step deposition of low-organic-containing conductive material followed by a high-organic-containing mechanical stabilizer will improve both the morphology of the conductive matrix and enlarge the contact area between the conductive material and the substrate (TCO). The process is preferably roll-to-roll, but use of rigid substrates is not excluded.

### Photovoltaic Device Chemistry

A variety of different chemistries to arrive at a desired semiconductor film for the absorber layer and the solution deposited transparent conductor is not limited to any particular type of solar cell or absorber layer. Although not limited to the following, an active layer for a photovoltaic device may be fabricated by formulating an ink of spherical and/or non-spherical particles each containing at least one element from groups IB, IIIA and/or VIA, coating a substrate with the ink to form a precursor layer, and heating the precursor layer to form a dense film. By way of nonlimiting example, the particles themselves may be elemental particles or alloy particles. In some embodiments, the precursor layer forms the desired group IB-IIIA-VIA compound in a one step process. In other embodiments, a two step process is used wherein a dense film is formed and then further processed in a suitable atmosphere to form the desired group IB-IIIA-VIA compound. It should be understood that chemical reduction and/or densification of the precursor layer may not be needed in some embodiments, particularly if the precursor materials are oxygen-free or substantially oxygen free. Thus, a first heating step of two sequential heating steps may optionally be skipped if the particles are processed air-free and are oxygen-free. The resulting group IB-IIIA-VIA compound for either a one step or a two step process is preferably a compound of Cu, In, Ga and selenium (Se) and/or sulfur S of the form CuIn₍₁₋ₓ₎GaₓS_{2(1-y)}Se_{2y}, where 0≦x≦1 and 0≦y≦1. Optionally, the resulting group IB-IIIA-VIA compound may be a compound of Cu, In, Ga and selenium (Se) and/or sulfur S of the form Cu_{z}In₍₁₋ₓ₎GaₓS_{2(1-y)}Se_{2y}, where 0.5≦z≦1.5, 0≦x≦1.0 and 0≦y≦1.0. Optionally, the resulting group IB-IIIA-VIA thin-film may be a mixture of compounds of Cu, In, Ga and selenium (Se) and/or sulfur S of the form Cu_{z}In₍₁₋ₓ₎GaₓS_{(2+w)(1-y)}Se_{(2+w)y}, where 0.5≦z≦1.5, 0≦x≦1.0, 0≦y≦1.0, and 0≦w≦0.5.

It should also be understood that group IB, IIIA, and VIA elements other than Cu, In, Ga, Se, and S may be included in the description of the IB-IIIA-VIA materials described herein, and that the use of a hyphen (“-”e.g., in Cu—Se or Cu—In—Se) does not indicate a compound, but rather indicates a coexisting mixture of the elements joined by the hyphen. It is also understood that group IB is sometimes referred to as group 11, group IIIA is sometimes referred to as group 13 and group VIA is sometimes referred to as group 16. Furthermore, elements of group VIA (16) are sometimes referred to as chalcogens. Where several elements can be combined with or substituted for each other, such as In and Ga, or Se, and S, in embodiments of the present invention, it is not uncommon in this art to include in a set of parentheses those elements that can be combined or interchanged, such as (In, Ga) or (Se, S). The descriptions in this specification sometimes use this convenience. Finally, also for convenience, the elements are discussed with their commonly accepted chemical symbols. Group IB elements suitable for use in the method of this invention include copper (Cu), silver (Ag), and gold (Au). Preferably the group IB element is copper (Cu). Group IIIA elements suitable for use in the method of this invention include gallium (Ga), indium (In), aluminum (Al), and thallium (Tl). Preferably the group MA element is gallium (Ga) and/or indium (In). Group VIA elements of interest include selenium (Se), sulfur (S), and tellurium (Te), and preferably the group VIA element is either Se and/or S. It should be understood that mixtures such as, but not limited to, alloys, solid solutions, and compounds of any of the above can also be used. The shapes of the solid particles may be any of those described herein.

### High Efficiency Cell Configuration

It should be understood that the device manufactured as shown in FIG. 1 and the above paragraphs may be suitable for use in a high efficiency cell configuration as detailed below in FIG. 4A. FIG. 4A illustrates an array 100 of optoelectronic devices according to an embodiment of the present invention. In some embodiments, this may be considered a series interconnection in an array 100 of optoelectronic devices. The array 100 includes a first device module 101 and a second device module 111. The device modules 101, 111 may be photovoltaic devices, such as solar cells, or light-emitting devices, such as light-emitting diodes. In a preferred embodiment, the device modules 101, 111 are solar cells. The first and second device modules 101, 111 are attached to an insulating carrier substrate 103, which may be made of a plastic material such as polyethylene terephthalate (PET), e.g., about 50 microns thick. The carrier substrate 103 may, in turn, be attached to a thicker structural membrane 105, e.g., made of a polymeric roofing membrane material such as thermoplastic polyolefin (TPO) or ethylene propylene diene monomer (EPDM), to facilitate installing the array 100 on an outdoor location such as a roof.

By way of nonlimiting example, the device modules 101, 111, which may be about 4 inches in length and 12 inches wide, may be cut from a much longer sheet containing several layers that are laminated together. Each device module 101, 111 generally includes a device layer 102, 112 in contact with a bottom electrode 104, 114 and an insulating layer 106, 116 between the bottom electrode 104, 114 and a conductive back plane 108, 118. It should be understood that in some embodiments of the present invention, the back plane 108, 118 may be described as a backside top electrode 108, 118. The bottom electrodes 104, 114, insulating layers 106, 116 and back planes 108, 118 for substrates S₁, S₂ support the device layers 102, 112

In contrast to prior art cells, where the substrates are formed by depositing thin metal layers on an insulating substrate, embodiments of the present invention utilize substrates S₁, S₂ based on flexible bulk conducting materials, such as foils. Although bulk materials such as foils are thicker than prior art vacuum deposited metal layers they can also be cheaper, more readily available and easier to work with. Preferably, at least the bottom electrode 104, 114 is made of a metal foil, such as aluminum foil. Alternatively, copper, stainless steel, titanium, molybdenum or other suitable metal foils may be used. By way of example, the bottom electrodes 104, 114 and back planes 108, 118 may be made of aluminum foil about 1 micron to about 200 microns thick, preferably about 25 microns to about 100 microns thick; the insulating layers 106, 116 may be made of a plastic foil material, such as polyethylene terephthalate (PET) about 1 micron to about 200 microns thick, preferably about 10 microns to about 50 microns thick. In one embodiment, among others, the bottom electrode 104, 114, insulating layer 106, 116 and back plane 108, 118 are laminated together to form the starting substrates S₁, S₂. Although foils may be used for both the bottom electrode 104, 114 and the back plane 108, 118 it is also possible to use a mesh grid on the back of the insulating layer 106, 116 as a back plane. Such a grid may be printed onto the back of the insulating layer 106, 116 using a conductive ink or paint. One example, among others, of a suitable conductive paint or ink is Dow Corning® PI-2000 Highly Conductive Silver Ink available from Dow Corning Corporation of Midland Mich. Dow Corning® is a registered trademark of Dow Corning Corporation of Midland Mich. Furthermore, the insulating layer 106, 116 may be formed by anodizing a surface of a foil used for the bottom electrode 104, 114 or back plane 108, 118 or both, or by applying an insulating coating by spraying, coating, or printing techniques known in the art.

The device layers 102, 112 generally include an active layer 107 disposed between a transparent conductive layer 109 and the bottom electrode 104. It should be understood that the transparent conductive layer 109 may be any of the solution deposited transparent conductors described herein. Optionally, the transparent conductor layer 109 may be metal rod, nanowire, web-like, or mesh-type electrode with sufficient spacing between elements so as to be substantially transparent in a spectral range from about 400 nm to about 1100 nm while still capable of carrying an electrical charge laterally. They may be with or without a binder. By way of example, the device layers 102, 112 may be about 2 microns thick. At least the first device 101 includes one or more electrical contacts 120 between the transparent conducting layer 109 and the back plane 108. The electrical contacts 120 are formed through the transparent conducting layer 109, the active layer 107, the bottom electrode 104 and the insulating layer 106. The electrical contacts 120 provide an electrically conductive path between the transparent conducting layer 109 and the back plane 108. The electrical contacts 120 are electrically isolated from the active layer 107, the bottom electrode 104 and the insulating layer 106.

The contacts 120 may each include a via formed through the active layer 107, the transparent conducting layer 109, the bottom electrode 104 and the insulating layer 106. Each via may be about 0.1 millimeters to about 1.5 millimeters, preferably 0.5 millimeters to about 1 millimeter in diameter. The vias may be formed by punching or by drilling, for example by mechanical, laser or electron beam drilling, or by a combination of these techniques. An insulating material 122 coats sidewalls of the via such that a channel is formed through the insulating material 122 to the back plane 108. The insulating material 122 may have a thickness between about 1 micron and about 200 microns, preferably between about 10 microns and about 200 microns.

The insulating material 122 should preferably be at least 10 microns thick to ensure complete coverage of the exposed conductive surfaces behind it. The insulating material 122 may be formed by a variety of printing techniques, including for example inkjet printing or dispensing through an annular nozzle. A plug 124 made of an electrically conductive material at least partially fills the channel and makes electrical contact between the transparent conducting layer 109 and the back plane 108. The electrically conductive material may similarly be printed. A suitable material and method, for example, is inkjet printing of solder (called “solderjet” by Microfab, Inc., Plano, Tex., which sells equipment useful for this purpose). Printing of conductive adhesive materials known in the art for electronics packaging may also be used, provided time is allowed subsequently for solvent removal and curing. The plug 124 may have a diameter between about 5 microns and about 500 microns, preferably between about 25 and about 100 microns.

By way of nonlimiting example, in other embodiments, the device layers 102, 112 may be about 2 microns thick, the bottom electrodes 104, 114 may be made of aluminum foil about 100 microns thick; the insulating layers 106, 116 may be made of a plastic material, such as polyethylene terephthalate (PET) about 25 microns thick; and the backside top electrodes 108, 118 may be made of aluminum foil about 25 microns thick. The device layers 102, 112 may include an active layer 107 disposed between a transparent conductive layer 109 and the bottom electrode 104. In such an embodiment, at least the first device 101 includes one or more electrical contacts 120 between the transparent conducting layer 109 and the backside top electrode 108. The electrical contacts 120 are formed through the transparent conducting layer 109, the active layer 107, the bottom electrode 104 and the insulating layer 106. The electrical contacts 120 provide an electrically conductive path between the transparent conducting layer 109 and the backside top electrode 108. The electrical contacts 120 are electrically isolated from the active layer 107, the bottom electrode 104 and the insulating layer 106.

The formation of good contacts between the conductive plug 124 and the substrate 108 may be assisted by the use of other interface-forming techniques such as ultrasonic welding. An example of a useful technique is the formation of gold stud-bumps, as described for example by J. Jay Wimer in “3-D Chip Scale with Lead-Free Processes” in Semiconductor International, Oct. 1, 2003, which is incorporated herein by reference. Ordinary solders or conductive inks or adhesives may be printed on top of the stud bump.

In forming the vias, it is important to avoid making shorting connections between the top electrode 109 and the bottom electrode 104. Therefore, mechanical cutting techniques such as drilling or punching may be advantageously supplemented by laser ablative removal of a small volume of material near the lip of the via, a few microns deep and a few microns wide. Alternatively, a chemical etching process may be used to remove the transparent conductor over a diameter slightly greater than the via. The etching can be localized, e.g., by printing drops of etchant in the appropriate places using inkjet printing or stencil printing.

A further method for avoiding shorts involves deposition of a thin layer of insulating material on top of the active layer 107 prior to deposition of the transparent conducting layer 109. This insulating layer is preferably several microns thick, and may be in the range of 1 to 100 microns. Since it is deposited only over the area where a via is to be formed (and slightly beyond the borders of the via), its presence does not interfere with the operation of the optoelectronic device. In some embodiments of the present invention, the layer may be similar to structures described in U.S. patent application Ser. No. 10/810,072 to Karl Pichler, filed Mar. 25, 2004, which is hereby incorporated by reference. When a hole is drilled or punched through this structure, there is a layer of insulator between the transparent conducting layer 109 and the bottom electrode 104 which may be relatively thick compared to these layers and to the precision of mechanical cutting processes, so that no short can occur.

The material for this layer can be any convenient insulator, preferably one that can be digitally (e.g. inkjet) printed. Thermoplastic polymers such as Nylon PA6 (melting point (m.p.) 223° C.), acetal (m.p. 165° C.), PBT (structurally similar to PET but with a butyl group replacing the ethyl group) (m.p. 217° C.), and polypropylene (m.p.165° C.), are examples which by no means exhaust the list of useful materials. These materials may also be used for the insulating layer 122. While inkjet printing is a desirable way to form the insulator islands, other methods of printing or deposition (including conventional photolithography) are also within the scope of the invention.

In forming the vias, it is useful to fabricate the optoelectronic device in at least two initially separate elements, with one comprised of the insulating layer 106, the bottom electrode 104 and the layers 102 above it, and the second comprised of the back plane 108. These two elements are then laminated together after the vias have been formed through the composite structure 106/104/102, but before the vias are filled. After this lamination and via formation, the back plane 108 is laminated to the composite, and the vias are filled as described above.

Although jet-printed solders or conductive adhesives comprise useful materials for forming the conductive via plug 124, it is also possible to form this plug by mechanical means. Thus, for example, a wire of suitable diameter may be placed in the via, forced into contact with the back plane 108, and cut off at the desired height to form the plug 124, in a manner analogous to the formation of gold stud bumps. Alternatively a pre-formed pin of this size can be placed into the hole by a robotic arm. Such pins or wires can be held in place, and their electrical connection to the substrate assisted or assured, by the printing of a very thin layer of conductive adhesive prior to placement of the pin. In this way the problem of long drying time for a thick plug of conductive adhesive is eliminated. The pin can have tips or serrations on it which punch slightly into the back plane 108, further assisting contact. Such pins may be provided with insulation already present, as in the case of insulated wire or coated wire (e.g. by vapor deposition or oxidation). They can be placed in the via before the application of the insulating material, making it easier to introduce this material.

If the pin is made of a suitably hard metal, and has a slightly tapered tip, it may be used to form the via during the punching step. Instead of using a punch or drill, the pin is inserted into the composite 106/104/102, to a depth such that the tip just penetrates the bottom; then when the substrate 108 is laminated to this composite, the tip penetrates slightly into it and forms a good contact. These pins may be injected into the unpunched substrate by, for example, mechanical pressure or air pressure directed through a tube into which the pin just fits.

The first device module 101 may be attached to the carrier substrate 103 such that the back plane 108 makes electrical contact with the thin conducting layer 128 while leaving a portion of the thin conducting layer 128 exposed. Electrical contact may then be made between the exposed portion of the thin conducting layer 128 and the exposed portion of the bottom electrode 114 of the second device module 111. For example, a bump of conductive material 129 (e.g., more conductive adhesive) may be placed on the thin conducting layer 128 at a location aligned with the exposed portion of the bottom electrode 114. The bump of conductive material 129 is sufficiently tall as to make contact with the exposed portion of the bottom electrode 114 when the second device module 111 is attached to the carrier substrate. The dimensions of the notches 117, 119 may be chosen so that there is essentially no possibility that the thin conducting layer 128 will make undesired contact with the back plane 118 of the second device module 111. For example, the edge of the bottom electrode 114 may be cut back with respect to the insulating layer 116 by an amount of cutback CB₁ of about 400 microns. The back plane 118 may be cut back with respect to the insulating layer 116 by an amount CB₂ that is significantly larger than CB₁. Optionally, the backside conductor or backplane 108 may be extended as shown by phantom section 131 to extend to be positioned below the bottom electrode 114 of an adjacent cell. In one embodiment, the two layers 131 and 114 may be connected together by a variety of methods such as but not limited to ultrasonic welding, laser welding, soldering, or other techniques to create an electrical connection. The layer 131 may be bent or shaped to better engage the section 114. Some embodiments may have holes, openings, or cutaways in the layer 131 to facilitate attachment.

The device layers 102, 112 are preferably of a type that can be manufactured on a large scale, e.g., in a roll-to-roll processing system. There are a large number of different types of device architectures that may be used in the device layers 102, 112. By way of example, and without loss of generality, the inset in FIG. 1A shows the structure of a CIGS active layer 107 and associated layers in the device layer 102. By way of example, the active layer 107 may include an absorber layer 130 based on materials containing elements of groups IB, IIIA and VIA. Preferably, the absorber layer 130 includes copper (Cu) as the group IB, Gallium (Ga) and/or Indium (In) and/or Aluminum as group IIIA elements and Selenium (Se) and/or Sulfur (S) as group VIA elements. Examples of such materials (sometimes referred to as CIGS materials) are described in U.S. Pat. No. 6,268,014, issued to Eberspacher et al on Jul. 31, 2001, and US Patent Application Publication No. US 2004-0219730 Al to Bulent Basol, published Nov. 4, 2004, both of which are incorporated herein by reference. A window layer 132 is typically used as a junction partner between the absorber layer 130 and the transparent conducting layer 109. By way of example, the window layer 132 may include cadmium sulfide (CdS), zinc sulfide (ZnS), or zinc selenide (ZnSe) or some combination of two or more of these. Layers of these materials may be deposited, e.g., by chemical bath deposition or chemical surface deposition, to a thickness of about 50 nm to about 100 nm. A contact layer 134 of a metal different from the bottom electrode may be disposed between the bottom electrode 104 and the absorber layer 130 to inhibit diffusion of metal from the bottom electrode 104. For example, if the bottom electrode 104 is made of aluminum, the contact layer 134 may be a layer of molybdenum.

Although CIGS solar cells are described for the purposes of example, those of skill in the art will recognize that embodiments of the series interconnection technique can be applied to almost any type of solar cell architecture. Examples of such solar cells include, but are not limited to: cells based on amorphous silicon, Graetzel cell architecture (in which an optically transparent film comprised of titanium dioxide particles a few nanometers in size is coated with a monolayer of charge transfer dye to sensitize the film for light harvesting), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Furthermore, embodiments of the series interconnection technique described herein can be used with optoelectronic devices other than solar cells.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although nanowires are disclosed as the shape for ease of discussion, it should be understood that any geometric shape such as rods of different aspect ratios, dog-bone shapes, round particles, oblong particles, single or multiple combinations of different geometric shapes, or other particle configurations may be used to form the percolating network herein.

It should be understood that the embodiments herein may be suitable for addressing web-like conductors made of other materials such as noble metal based or noble metal nanoarchitected webs or meshes (or their alloys) and are not limited to the nanowires. It should be understood that the nanowires layer may be deposited in one step and a binder applied in a second step. Optionally, the binder and web-like conductors are applied simultaneously. In some embodiments, the web-like conductors are suspended in dispersion with a layer of material (such as for the junction partner or the transparent conductor) and solution deposited simultaneously. Some embodiments may have a layer of web-like transparent conductor and then a layer of ZnO on top. Optionally, the positions may be reversed with the ZnO on the bottom and the web-like transparent conductor on top. As mentioned, the use of ZnO is purely exemplary and other transparent materials may be used. Some embodiments may include coated nanowires such as but not limited to coated nanowires with corrosion resistant layers of gold or other materials over the nanowires using techniques such as but not limited to those described by Olga Krichevski et al in Formation of Gold-Silver Nanowires in Thin Surfactant Solution Films, Langmuir, 2006, 22 (3), pp 867-870 or Growth of Au/Ag nanowires in thin surfactant solution films: An electron microscopy study in Journal of Colloid and Interface Science, Volume 314, Issue 1, 1 October 2007, Pages 304-309, both fully incorporated herein by reference for all purposes. Embodiments of nanostructured layers and nanowires are discussed in U.S. patent application Ser. No. 11/375,515 filed Mar. 13, 2006 and fully incorporated herein by reference for all purposes.

Furthermore, those of skill in the art will recognize that any of the embodiments of the present invention can be applied to almost any type of solar cell material and/or architecture. For example, the absorber layer in the solar cell may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, Cu—In, In—Ga, Cu—Ga, Cu—In—Ga, Cu—In—Ga—S, Cu—In—Ga—Se, II-VI materials, IB-VI materials, CuZnTe, CuTe, ZnTe, other absorber materials, IB-IIB-IVA-VIA absorbers, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Optionally, some embodiments may be from a group IB-IIB- IVA-VIA compound absorber layer. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc . . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. patent application Ser. Nos. 60/909,357 filed Mar. 30, 2007, 60/913,260 filed Apr. 20, 2007, U.S. Provisional Application Ser. No. 61/109,898 filed Oct. 30, 2008, and U.S. Patent Publication 2007/0074316 are fully incorporated herein by reference for all purposes. The following papers are also included herein by reference for all purposes: G. A. Gelves et al “Low Electrical Percolation Threshold of Silver and Copper Nanowires in Polystyrene Composites” in Advanced Functional Materials, Volume 16 Issue 18, Pages 2423-2430 published 2006, Hsu, H. P.; M. C. Huang (1999). “Percolation thresholds, critical exponents, and scaling functions on planar random lattices and their duals”. Physical Review E 60 (1999): 6361-6370, Suding, P. N.; R. M. Ziff (1999). “Site percolation thresholds for Archimedean lattices”. Physical Review E 60 (1): 275-283, Parviainen, Robert (2007). “Estimation of bond percolation thresholds on the Archimedean lattices”. J. Phys. A 40: 9253-9258., Ziff, R. M.; Hang Gu (2009). “Universal condition for critical percolation thresholds of kagomé-like lattices”. Phys. Rev. E 79 (2): 020102R, and ykes, M. F.; J. W. Essam (1964). “Exact critical percolation probabilities for site and bond problems in two dimensions”. Journal of Mathematical Physics (N.Y.) 5 (8): 1117-1127.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A method comprising:
forming a solar cell having: a) a thinner than usual transparent top electrode of a conductive material having a thickness of 50 nm or less and b) an interconnected network of nanowires in contact with and/or coated by the top electrode.

2. The method of claim 1 wherein the top electrode and network of nanowires increases overall power output of the solar cell compared to an otherwise identical cell using only a) a top electrode layer of the material at a thickness and light transmission equal to a combined thickness and light transmission of the top electrode and the network of nanowires, or b) an interconnected network of nanowires of thickness equal to the combined thickness and light transmission.

3. The method of claim 1 wherein the nanowires are coated plainly in a solvent only and no binder.

4. The method of claim 3 further comprising subsequently overcoating the nanowires with a binder.

5. The method of claim 4 wherein the binder is an electrically conductive polymer.

6. (canceled)

7. The method of claim 1 wherein a maximum distance from any location in the transparent top electrode to a nearest nanowire in the network is in the range between 1 to 10 microns.

8. The method of claim 1 wherein a maximum distance from any location in the transparent top electrode to a nearest nanowire in the network is in the range between 2 to 5 microns.

9. The method of claim 1 wherein the transparent top electrode without the nanowires has an electrical resistance of at least about 500 ohms per square or more.

10. The method of claim 1 wherein the transparent top electrode without the nanowires has an electrical resistance of at least about 300 ohms per square or more.

11. The method of claim 1 comprising sputtering the transparent top electrode material over the nanowires.

12. The method of claim 1 wherein the nanowires are randomly oriented.

13. The method of claim 1 wherein the nanowires are coupled to the transparent top electrode using pressure, without an annealing step, to connect nanowires to form a percolating network.

14. The method of claim 1 wherein the nanowires are coupled to the transparent top electrode without heating above 150 C.

15. The method of claim 1 wherein the nanowires are coupled to the transparent top electrode without heating above 100 C.

16. The method of claim 1 wherein light transmission through the top electrode with the network layer of nanowires is at least 90% light transmission.

17. A method comprising:
forming a photovoltaic absorber layer and a junction partner layer;
forming a hybrid transparent conductive layer of a first thickness, the layer comprising:
an isotropic layer for gathering charge from the junction partner layer;
a nanowire network layer in contact with the isotropic layer;
wherein the hybrid transparent conductive layer increases overall photovoltaic efficiency of the cell compared to a cell using only a) an isotropic layer of a thickness equal to the first thickness or b) a nanowire network layer of thickness equal to the first thickness.

18. The method of claim 17 comprising:
wherein the hybrid transparent conductive layer has a thickness of 50 nm or less and is thinner than usual transparent top electrode, wherein the hybrid transparent conductive layer without the nanowires has an electrical resistance greater than 200 ohms per square.

19. (canceled)

20. (canceled)

21. The method of claim 17 wherein the isotropic layer is conformal to an upper surface of the absorber layer.

22. The method of claim 17 wherein the isotropic layer has at least a bottom surface in conformal contact with an upper surface of the absorber layer so that the isotropic layer can gather charge from the absorber layer.

23. The method of claim 17 wherein the nanowire layer has sufficient spacing between nanowires so as to be substantially transparent in wavelengths between about 400 nm to 800 nm.

24. The method of claim 17 wherein the isotropic layer comprises a sol-gel layer.

25. (canceled)
